(19) United States
(12) Patent Application Publication
(10) Pub. No.: US 2002/0163031 A1
(43) Pub. Date: Nov. 7, 2002

(54) Dual-bit flash memory built from a discontinuous floating gate

(76) Inventors: Chien-Hung Liu, Taipei City (TW); Erh-Kun Lai, Taichung Hsien (TW); Shyi-Shuh Pan, Kaoshiung City (TW); Shou-Wei Huang, Keelung City (TW); Ying-Tzoo Chen, Kaoshiung Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/846,179

(22) Filed: May 2, 2001

(51) Int. Cl. H01L 29/788

(52) U.S. Cl. 257/315

(57) ABSTRACT

A dual-bit flash memory forming by discontinuous floating gates is disclosed. The memory cell of the dual-bit flash memory contains a P type semiconductor substrate or an N type semiconductor substrate with a source and a drain therein. At least two floating gates are installed on the semiconductor substrate between the source and the drain. A tunneling dielectric layer is used to isolate the floating gates and the semiconductor substrate. An insulated dielectric layer is formed on the surface of the floating gates and the central exposed semiconductor substrate. Then, another control gate is formed on the insulated dielectric layer. Thereby, a dual-bit flash memory cell is formed. In the present invention, under a condition of without increasing the density of the unit memory cell, the capacity of memory is twice.

### FIELD OF THE INVENTION

The present invention relates to a non-volatile memory, and especially to a dual-bit flash memory built from discontinuous floating gates.

### BACKGROUND OF THE INVENTION

Flash memories are widely used in various mini-type electronic applications, such as notebook computers, digital cameras, etc. With a trend of compact sizes of electronic products, the size of the flash memory is smaller and smaller.

The flash memory is a kind of non-volatile memory based on floating gate transistors. In that, memory cells are arranged as an array with a way suitable for their applications and are used to store data of a bit. In this array, each memory cell is formed with a source 12 and a drain 14 on a P type semiconductor substrate by ion-plantation. A stacked gate 16 is installed on the semiconductor substrate 10 between the source 12 and the drain 14, which are sequentially consisted of an oxidized dielectric layer 18, a floating gate 20 for storing charges, an insulated dielectric layer 22 and a control gate 24 for controlling the accessing of data. The memory condition of the flash memory is determined by the concentration of charges in the floating gate 20, while the operation thereof is determined by the technology of injecting or removing charges from the floating gate 20.

By controlling the applying voltages of the source 12 and drain 14, a channel and hot electrons are formed in the semiconductor substrate 10 below the floating gate 20. Through a hot electron injection principle, these hot electrons pass through the oxidized insulating layer from the drain 14 to the floating gate 20 for accomplishing a process of programming reading and writing data. On the contrary, by Fowler-Nordheim tunnel (F-N tunnel) effect, electrons are released from the floating gate 20 to the source 12 so as to erase data.

Since in aforesaid structure of the flash memory, each memory cell may store one bit, the capacity of the memory is limited and thus is not sufficient nowadays. The integrated density of each unit memory cell is necessary to be increased so as to increase the memory cells for storing data in unit area. However, in order to increase the efficiencies of programming data writing and reading in a flash memory, each memory cell must has a higher area for acquiring a high capacitive coupling ratio. Therefore, the area of unit memory cell can not be reduced and thus the integrated density of memory cell can not be improved effectively for increasing the storing capacity of the prior art flash memory.

Therefore, in the present invention, under a condition of without increasing the integrated density of the unit memory cell, a memory with twice capacity of the prior art design is disclosed for resolving the aforesaid detects in the prior art.

### SUMMARY OF THE INVENTION

Accordingly, the primary object of the present invention is to provide a dual-bit flash memory forming by discontinuous floating gates which has two floating gates as two charge storing areas so that the capacity of a memory becomes twice of the prior art memory. Furthermore, the charge storing area of the two floating gates is controlled by the matching of the source, drain and gates.

Another object of the present invention is to provide a dual-bit flash memory forming by discontinuous floating gates, the control gate is directly adjacent to the channel of the semiconductor substrate passing through the floating gates so that the capacitive coupling ratio is increased greatly.

To achieve above objects, the present invention provides dual-bit flash memory forming by discontinuous floating gates, wherein a source and a drain with doped N⁺ ions are installed in a P type semiconductor substrate. A tunneling dielectric layer is positioned on the surface of the semiconductor substrate connected the source and the drain. Two floating gates are formed on the tunneling dielectric layer. An insulated dielectric layer and a control gate are sequentially formed thereon for being formed as a dual-bit flash memory.

The various objects and advantages of the present invention will be more readily understood from the following detailed description when read in conjunction with the appended drawing.

### BRIEF DESCRIPTION OF THE DRAWINGS

FIG. 1 is a schematic view showing the structure of a prior art flash memory.

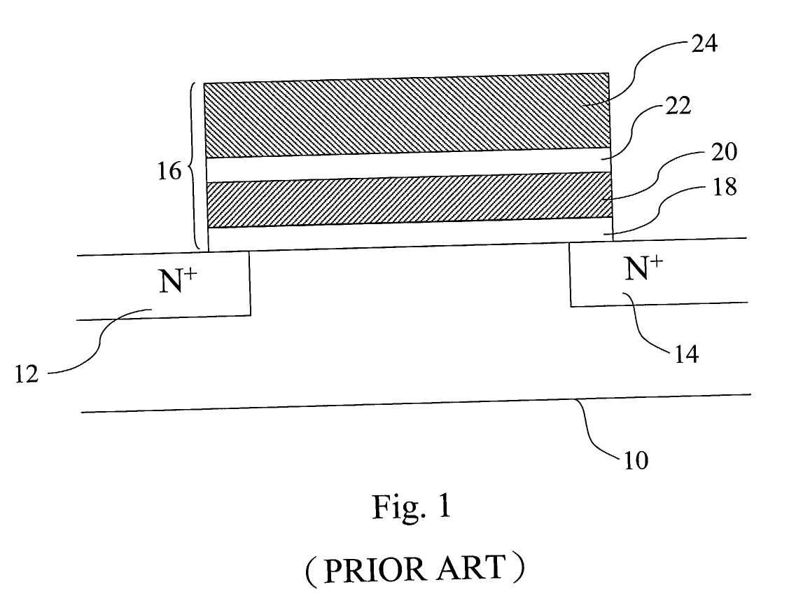

FIG. 2 is a schematic view showing the structure of the present invention.

FIG. 3 shows another embodiment of the present invention.

### DETAILED DESCRIPTION OF THE PREFERRED EMBODIMENTS

The feature of the present invention is to use discontinuous floating gates to build a dual-bit flash memory so that each flash memory has at least two floating gates as charge storage areas so that under a condition without changing the integrated density of unit memory, the capacity of a memory becomes twice of the prior art memory. In the following, a flash memory with a P type semiconductor substrate is used as an embodiment, thereby, the those skilled in the art may understand the present invention fully.

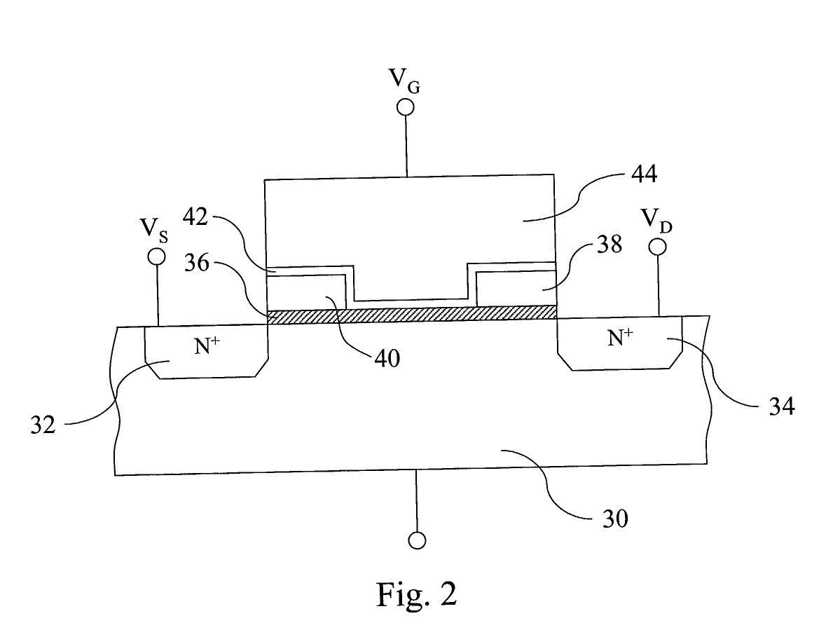

Referring to FIG. 2, a single memory cell of a dual-bit flash memory is illustrated. Two N⁺ ion doping areas are formed in the P type semiconductor substrate 30 by ion-planting method, which are used as a source 32 and a drain 34. A tunneling dielectric layer 36 is formed above the P type semiconductor substrate 30. This tunneling dielectric layer 36 is an oxide layer. Two separated floating gates 38, 40 are installed on the surface of this tunneling dielectric layer 36 for storing charges. Two floating gates 38, 40 are electrically isolated by the tunneling dielectric layer 36, drain 34, and source 32. An insulated dielectric layer 42 is formed on the surfaces of the floating gates 38, 40, and the exposed surface of the P type semiconductor substrate 30 between the two floating gates. Further, a control gate 44, for example, a high doped polysilicon gate, is formed on the surface of the insulated dielectric layer 42 for controlling the accessing of data so that an area of no floating gate is formed between the control gate 44 and the P type semiconductor substrate 30.

In general, the aforesaid insulated dielectric layer 42 is an oxide layer, which can be constructed by an oxide layer, a nitride layer (in general, a nitride silicon layer), and an oxide layer (an oxide-nitride-oxide film, simplified as ONO film).

By the variation of the external voltage of the control gate 44, source 32, and the drain 34, the area in the P type semiconductor substrate 30 while below the floating gates 38, 40 and between the source 32 and the drain 34 is formed as a channel and generates hot electrons for the operations of the programming, erasing and reading of the dual-bit flash memory. Since part of the control gate 44 of the dual-bit flash memory is directly adjacent to the P type semiconductor substrate 30 without passing through the floating gates 38, 40, the capacitive coupling ratio is increased greatly.

The operation way with respect to the construction of the dual-bit flash memory cell will be described in the following. In this method, the structure of the memory cell illustrated in FIG. 2 is used. In this operation way, the source 32, drain 34, and control gate 44 of the flash memory are applied with a source voltage (Vs), a drain voltage (VD), and a gate voltage (VG) for the programming, erasing and reading operations of the memory cell.

When a programming process is performed to a right bit, the positive voltage VG applied to the control gate 44 is 10 V (high), the voltage VD applied to the drain 34 is 10V, and the voltage Vs applied to the source 32 is 0V. The P type semiconductor substrate 30 is grounded. Therefore, the hot electrons near the channel of the drain 34 is injected into the floating gate 38 of the right bit by a hot electron injecting method.

When an erasing process is performed to the right bit, the voltage VG applied to the control gate 44 is −5 V (low), the voltage VD applied to the drain 34 is 5V, and the source 32 is floating. The P type semiconductor substrate 30 is grounded. Therefore, electrons in the right bit floating gate 38 is transferred to the drain 34 by F-N tunnel effect so as to achieve an object of erasing.

When a reading process is performed to the right bit, the positive voltage VG applied to the control gate 44 is 5 V (high), the voltage VD applied to the drain 34 is 0V, and the voltage Vs applied to the source 32 is 3V. The P type semiconductor substrate 30 is grounded. Therefore, the reading to the right bit floating gate 38 of this flash memory cell is complete.

In aforementioned description about the operations of programming, erasing, and reading, a right bit is used as an example, while for the operations of programming, erasing or reading, it is only necessary that the gate voltage VG is retained to the original condition, while the applied voltages of the source voltage Vs and drain voltage VD are interchanged. Thus, the operations of programming, erasing, and reading of left bit is complete.

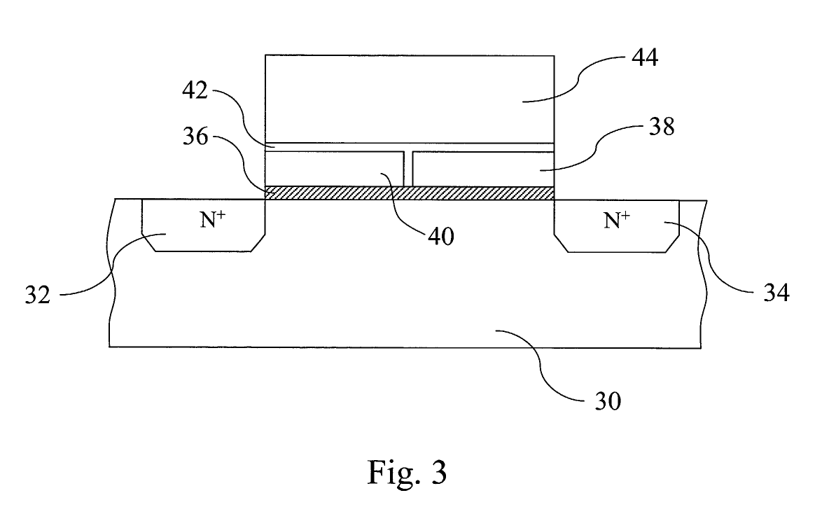

In the FIG. 2, the structure of the dual-bit flash memory is two separated floating gates 38, 40. Besides, the two floating gates 38, 40 may be adjacent to one another as that shown in FIG. 3. Two adjacent floating gates 38, 40 are directly located on the surface of the tunneling dielectric layer 36 and an insulated dielectric layer 42 and a control gate 44 are directly formed thereon. The functions and operations of this flash memory are identical to the aforesaid one.

Therefore, in the present invention, two discontinuous floating gates are used as two charge storing areas for increasing the memory capacity to be twice of that in the prior art. The operation of the left and right bits in the charge storing area of the two floating gates is controlled by the matching of the source, drain and gates.

Furthermore, in the structure and operation of the present invention, a dual-bit flash memory with a P type semiconductor substrate is used as an example, while a memory structure formed by an N type semiconductor substrate can be used to achieve the same effects. In that, the flash memory cell with an N type semiconductor substrate, the ion doping areas for the source and drain is changed as P⁺ ion doping area, while the other structures and relative positions are identical to those aforesaid, and thus, the details will not be further described herein.

The present invention are thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A dual-bit flash memory forming by discontinuous floating gates comprising:
a semiconductor substrate having a plurality of ion doping areas for being used as a source and a drain;
at least two floating gates installed on a surface of said semiconductor substrate between said source and said drain, said floating gates being isolated with said source and said drain through a tunneling dielectric layer;
an insulated dielectric layer being formed on surfaces of said two floating gates and an surface of said semiconductor substrate between the two floating gates; and
a control gate being formed on a surface of said insulated dielectric layer.

2. The dual-bit flash memory as claimed in claim 1, wherein said semiconductor substrate is selected from one of a group containing a P type semiconductor substrate or an N type semiconductor substrate.

3. The dual-bit flash memory as claimed in claim 1, wherein ion doping areas of said source and said drain are doped by ions of the same type which is selected from one of a group containing a P type ion and an N type ion.

4. The dual-bit flash memory as claimed in claim 1, wherein said two floating gates are adjacent so that said semiconductor substrate is not exposed.

5. The dual-bit flash memory as claimed in claim 1, wherein said floating gates are made of conductive materials.

6. The dual-bit flash memory as claimed in claim 1, wherein said tunneling dielectric layer is made of oxide.

7. The dual-bit flash memory as claimed in claim 1, wherein said insulated dielectric layer is constructed by an oxide layer, a nitride layer and an oxide layer, i.e., an oxide-nitride-oxide film, simplified as ONO film.

8. The dual-bit flash memory as claimed in claim 1, wherein said insulated dielectric layer is made of oxide.
